(19) United States
(12) Patent Application Publication
(10) Pub. No.: US 2011/0193617 A1
(43) Pub. Date: Aug. 11, 2011

(54) SEMICONDUCTOR CARD

(75) Inventors: Atsushi YOSHIMOTO, Osaka (JP); Takashi KAKIMOTO, Kyoto (JP); Osamu ISHIKAWA, Kyoto (JP)

(73) Assignee: PANASONIC CORPORATION, Osaka (JP)

(21) Appl. No.: 13/090,529

(22) Filed: Apr. 20, 2011

Related U.S. Application Data
(63) Continuation of application No. PCT/JP2010/001491, filed on Mar. 4, 2010.

(30) Foreign Application Priority Data
Mar. 12, 2009 (JP) 2009-059467

(51) Int. Cl. G05F 1/00; H05K 7/00; H05K 7/20

(52) U.S. Cl. 327/518; 361/748; 361/688

(57) ABSTRACT

Portability of an electronic device with a semiconductor card is improved. The semiconductor card is insertable to a card slot in an electronic device, can engage a card socket formed inside the card slot, and has a base part and an expansion part. The base part has a terminal part and a first connection unit, and engages the card socket with the terminal part. The expansion part has a second connection unit, and can be moved between two positions when the second connection unit is connected to the first connection unit, a closed position where the expansion part is overlapping and substantially parallel to the base part, and an open position where the expansion part is extended at an angle greater than a perpendicular with respect to the base part. When the expansion part is in the closed position and the terminal part is engaged in the card socket, the expansion part and the base part are inserted to the card slot. When in the open position with the terminal part engaged in the card socket, the base part is inserted to the card slot and part of the expansion part protrudes from the card slot.

### CROSS-REFERENCE TO RELATED APPLICATIONS

This is a continuation application of International Application No. PCT/JP2010/001491, filed Mar. 4, 2010 entitled “SEMICONDUCTOR CARD” and claims priority to Japanese Patent Application No. 2009-059467 filed Mar. 12, 2009, the content of which is incorporated by reference herein.

### BACKGROUND OF THE INVENTION

(1) Field of the Invention

The present invention relates to a semiconductor card, and relates more particularly to a Secure Digital Input Output (SDIO) card, which is a type of semiconductor card defined by the SD Card Association as an SD card with extended input/output functions that is compatible with postage stamp size Secure Digital (SD) cards, a type of semiconductor card standardized by the SD Card Association.

(2) Description of Related Art

SDIO cards are widely used to add memory and an input/output interface to portable electronic devices such as portable computers and PDA (Personal Digital Assistant) devices. SDIO cards that have a Bluetooth (R) or other wireless communication function, for example, and enable sending and receiving data wirelessly between multiple electronic devices are also available.

An SDIO card with a wireless communication capability has a card case inside of which are a communication circuit, an interface circuit, and an antenna. The card case enables insertion to the card slot of an electronic device similarly to any common SDIO card. The antenna and communication circuit for wireless communication are located at the opposite end as the insertion end of the card case. When the card case is inserted to the card slot, the antenna part of the card case is held protruding from the card slot to the outside of the electronic device. This enables orienting the antenna in the desired direction outside the card slot to maximize the signal reception level and minimize the required transmission power, thereby enabling good wireless communication.

However, if an unavoidable impact or load is applied in the direction of the card thickness to the protruding part of the card, stress is concentrated around the border between the inserted part that is inside the card slot and the exposed outside part, and SDIO card function and performance can be adversely affected.

Japanese Unexamined Patent Appl. Pub. JP-A-2003-006603 proposes a solution to this problem. As shown in FIG. 7A and FIG. 7B, the semiconductor card taught in JP-A-2003-006603 has a first part 18a that is inserted to the card slot, and a second part 18b (protruding part) that protrudes from the card slot. The first part 18a and second part 18b are connected at a joint 27. As shown in FIG. 7C and FIG. 7D, the flexing action of this joint 27 serves to relieve the bending force applied to the first part 18a and second part 18b.

The semiconductor card taught in JP-A-2003-006603, however, does nothing more than bend in order to escape the force of impact and loads applied to the protruding part. One problem is therefore that the protruding part remains protruding from the card slot when the semiconductor card is loaded in the card slot, and this protruding part interferes with the portability of the electronic device when the electronic device is carried with the semiconductor card installed in the card slot.

A second problem is that the joint is easily damaged when a strong impact or load is applied to the protruding part in the thickness direction and the protruding part is bent beyond the range of movement of the joint.

As a result, when an electronic device with an inserted semiconductor card is carried somewhere, the semiconductor card must be removed from the card slot each time and carried separately from the electronic device. As a result, the semiconductor card can be forgotten or lost after it is removed. In addition, when a semiconductor card with a joint is carried alone, the joint can move freely, is unstable, and can be damaged. A third problem is therefore the danger of loss or damage arising from handling the semiconductor card alone.

The size of the protruding part also depends upon the functions incorporated in the semiconductor card. When WLAN (Wireless LAN), Bluetooth, or ZigBee are used, the protruding part can be eliminated or made relatively small. However, when the semiconductor card uses telecommunication technologies such as UMTS (Universal Mobile Telecommunications System) or GSM (Global System for Mobile Communications) technology, the necessary hardware components result in a relatively large protruding part. As a result, a fourth problem is that this increases the importance of the first and second problems noted above.

Another reason for having a protruding part such as described above is so that heat produced by the communication circuit can escape into the air. Designs that control wireless communication power according to the signal reception level are commonly used to suppress the heat output of the communication circuit. More specifically, when the signal reception level is low, the transmitter (such as the base station) is determined to be relatively far and transmission power is increased, but when the signal reception level is high, the transmitter is determined to be relatively close and transmission power is reduced. As a result, transmission performance can be improved when the other party is relatively far away, and power consumption and heat output can be reduced when the other part is relatively close.

By reducing the size of the communication circuit, antenna, and other parts that protrude to the outside, they could be housed with the semiconductor card completely inside the card slot of the electronic device. However, if the signal reception level drops because the direction of the antenna is fixed, the heat output of the communication circuit rises because transmission power is increased as described above. The temperature of the semiconductor card therefore rises because the semiconductor card is contained within the electronic device and heat from the communication circuit cannot dissipate. A fifth problem is therefore that semiconductor card function and performance become damaged and the card case can be deformed by heat from the communication circuit.

A sixth problem is that even if the semiconductor card can be housed completely within the card slot, heat produced by the communication circuit cannot dissipate, transmission power cannot be increased, and the transmission performance of the semiconductor card is thus insufficient.

Note that transmission performance as used herein is the ability to transmit RF signals so that they reach the other party with a sufficient signal reception level.

### BRIEF SUMMARY OF THE INVENTION

The invention is directed to solving the foregoing problems by providing a semiconductor card that improves the portability of the electronic device in which the semiconductor card is installed.

According to one aspect of the invention, a semiconductor card that is insertable to a card slot in an electronic device and engagable to a card socket formed inside the card slot, comprises: a base part having a terminal part and a first connection unit, the terminal part being engagable to the card socket; and an expansion part having a second connection unit, the expansion part being movable between two positions when the second connection unit is connected to the first connection unit, a closed position where the expansion part is overlapping and substantially parallel to the base part, and an open position where the expansion part is extended at an angle greater than a perpendicular with respect to the base part. When the expansion part is in the closed position and the terminal part is engaged in the card socket, the expansion part and the base part are inserted to the card slot. When the expansion part is in the open position and the terminal part is engaged in the card socket, the base part is inserted to the card slot and at least a part of the expansion part protrudes from the card slot.

An electronic device according to another aspect of the invention can use the semiconductor card described above.

### Effect of the Invention

A semiconductor card according to the invention can be set to two positions, an open position and a closed position. The semiconductor card and the expansion part thereof can be stored completely inside the card slot when in the closed position. In the open position, at least part of the expansion part protrudes to the outside of the electronic device from the card slot.

As a result, the semiconductor card can be positioned to optimally orient the antenna for good wireless reception when in the open position using at least a part of the expansion part protruding from the card slot. In the closed position, no part of the semiconductor card protrudes from the electronic device, damage to the semiconductor card can therefore be prevented, and portability of the electronic device is improved. In addition, because the semiconductor card can be carried inside the electronic device, loss of or damage to the semiconductor card resulting from being handled separately can be prevented.

Other objects and attainments together with a fuller understanding of the invention will become apparent and appreciated by referring to the following description and claims taken in conjunction with the accompanying drawings.

### BRIEF DESCRIPTION OF THE SEVERAL VIEWS OF THE DRAWINGS

FIG. 1A is an oblique view of a semiconductor card according to a first embodiment of the invention when folded closed.

FIG. 1B is a plan view, bottom view, front view, and side view of the semiconductor card according to a first embodiment of the invention when folded closed.

FIG. 1C is a front view showing the semiconductor card according to the first embodiment of the invention when open to the extended position.

FIG. 1D is a bottom view, front views and side view of a semiconductor card according to a variation of the first embodiment of the invention.

FIG. 2 is an oblique view of a semiconductor card according to the first embodiment of the invention when closed and inserted in an electronic device.

FIG. 3A is a section view of a semiconductor card according to the first embodiment of the invention when closed and inserted in an electronic device.

FIG. 3B is an oblique view of a card socket according to the first embodiment of the invention.

FIG. 4A is a plan view and a bottom view showing the circuit arrangement of a semiconductor card according to the first embodiment of the invention.

FIG. 4B is a plan view and a bottom view showing the circuit arrangement of a semiconductor card according to a second variation of the first embodiment of the invention.

FIG. 5 is a section view showing a variation of a semiconductor card according to the first embodiment of the invention when inserted in an electronic device.

FIG. 6 is a plan view, bottom view, front view, and side view of a semiconductor card according to a second embodiment of the invention, and an oblique view of an electronic device.

FIG. 7A is an oblique view of a semiconductor card and electronic device according to the related art.

FIG. 7B is a front view and a side view of a semiconductor card and electronic device according to the related art.

FIG. 7C is a side view of a semiconductor card and electronic device according to the related art.

FIG. 7D is another side view of a semiconductor card and electronic device according to the related art.

### DETAILED DESCRIPTION OF THE INVENTION

Preferred embodiments of the present invention are described below with reference to the accompanying figures. Note that parts having the same configuration, operation, and effective are identified using the same reference numerals in the figures.

### Embodiment 1

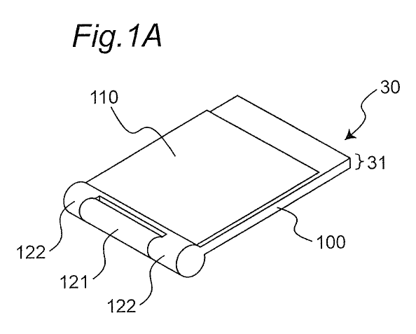

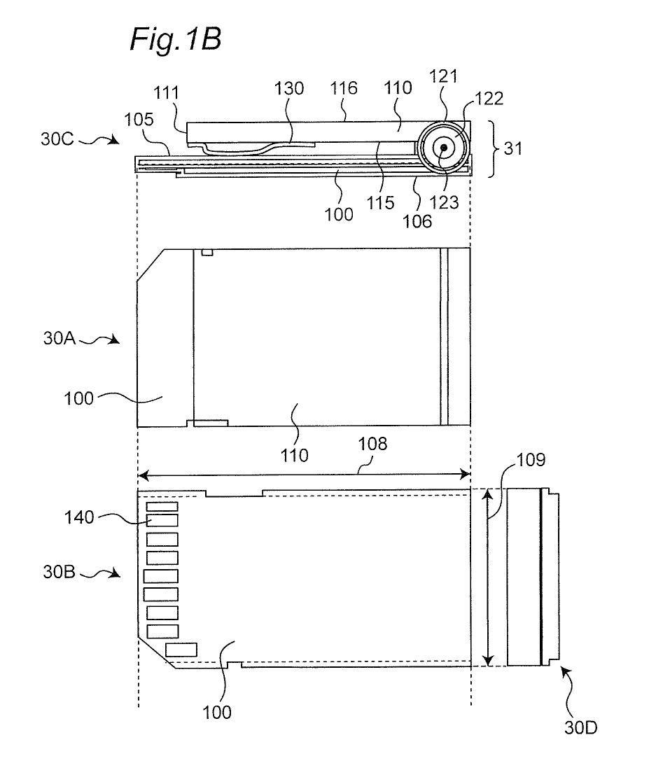

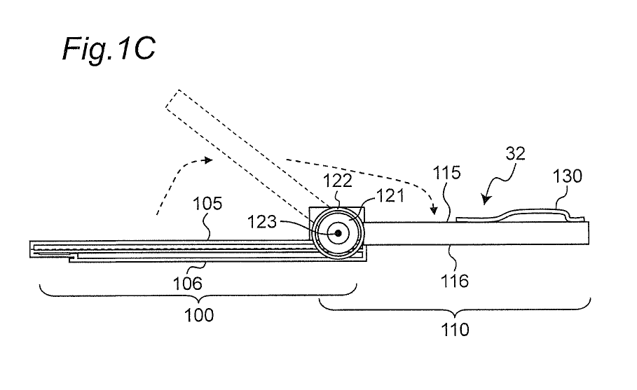

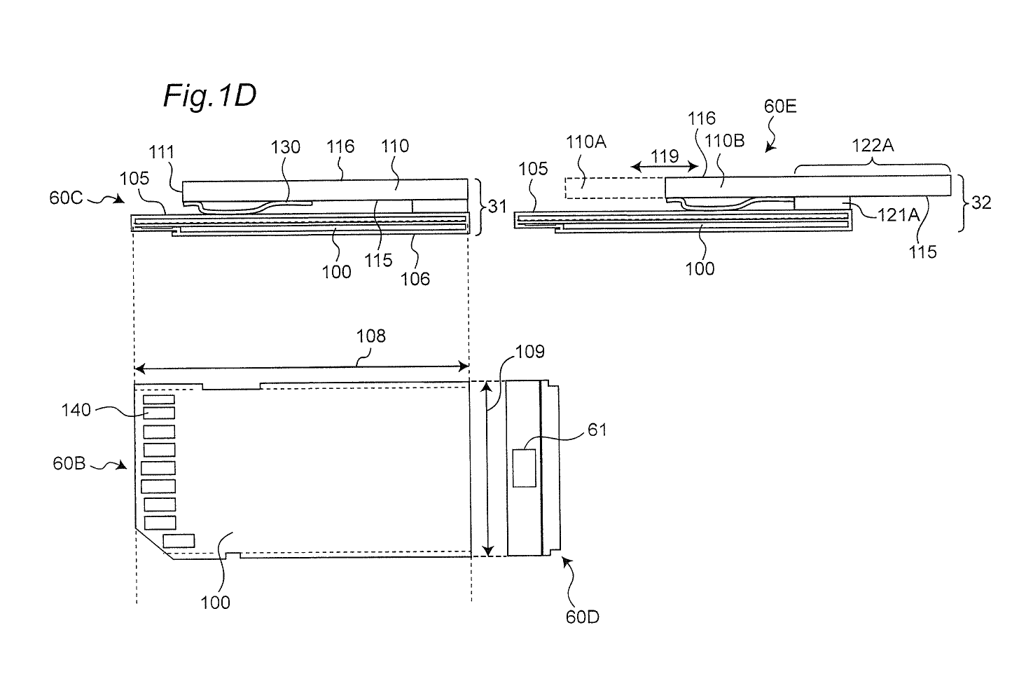

FIG. 1A is an oblique view of a semiconductor card 30.

FIG. 1B shows a plan view 30A, bottom view 30B, front view 30C, and side view 30D of the semiconductor card 30.

FIG. 1C is a front view of the semiconductor card 30.

FIG. 1D shows a bottom view 60B, front view 60C, side view 60D, and front view 60E of a variation of the semiconductor card 30.

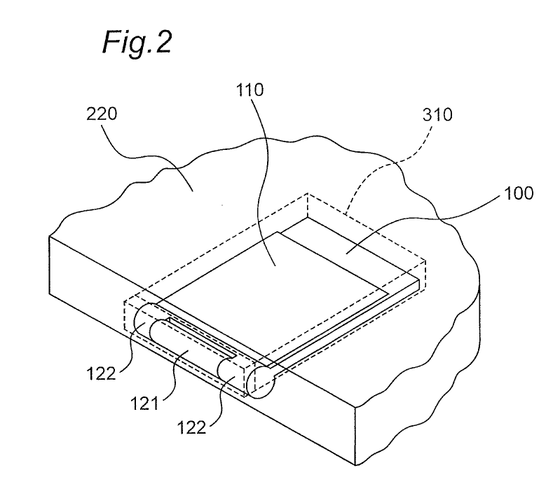

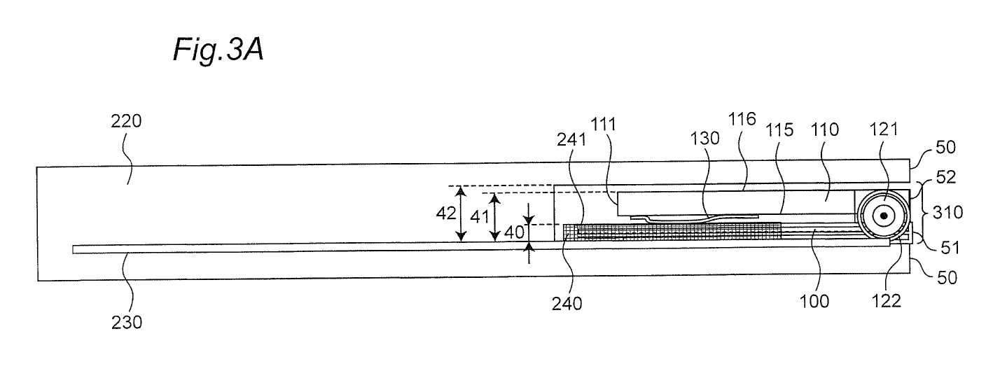

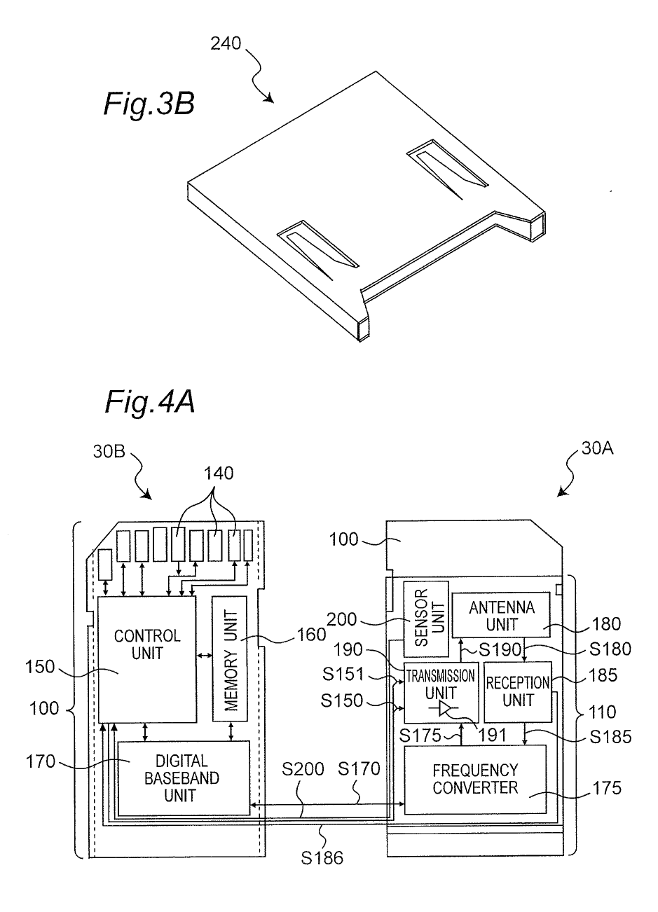

The semiconductor card 30 is, for example, an SDIO (Secure Digital Input Output) card. An SDIO card is a semiconductor card that is standardized by the SD Card Association as an SD card that is compatible with SD (Secure Digital) cards and has expanded input/output capabilities. SDIO cards are used with portable computers, PDAs (Personal Digital Assistants), and other portable electronic devices 220 (described with reference to FIG. 2 and FIG. 3A below) as expansion cards providing additional memory and I/O interface, for example.

The semiconductor card 30 includes a base part 100 and an expansion part 110.

The base part 100 includes a terminal part 140 and a base part connection unit 121. The terminal part 140 is located at one end of the length 108 of the base part 100, and the base part connection unit 121 is located at the other end of the base part 100.

The expansion part 110 includes a expansion part connection unit 122. The expansion part connection unit 122 is located at one end of the length 108 of the expansion part 110.

The expansion part connection unit 122 connects to the base part connection unit 121 like a hinge, and can pivot on the connection shaft 123. The expansion part 110 can be set to either of two positions with the expansion part connection unit 122 connected to the base part connection unit 121. A first position is the closed position 31 where the expansion part 110 is folded over to and substantially parallel with the base part 100 (shown in the front view 30C in FIG. 1A and FIG. 1B). A second position is the open position 32 shown in FIG. 1C to which the expansion part 110 extends through an angle perpendicular to the base part 100. More specifically, the angle formed by the expansion part 110 to the base part 100 when in the open position 32 is greater than or equal to 90 degrees and less than or equal to 180 degrees.

In the closed position 31, the inside surface 115 of the expansion part 110 is opposite the inside surface 105 of the base part 100 with a specific distance therebetween, and the outside surface 116 of the expansion part 110 and the outside surface 106 of the base part 100 face in opposite directions.

In the open position 32, the inside surface 115 of the expansion part 110 faces substantially the same direction as the inside surface 105 of the base part 100 (that is, is extended to an open angle of substantially 180 degrees) and the outside surface 116 of the expansion part 110 and the outside surface 106 of the base part 100 both face the opposite direction as the inside surfaces 105, 115. The expansion part 110 can pivot on the connection shaft 123 and can be held in any desired position between this closed position 31 and the open position 32.

The base part connection unit 121 is pillar shaped, and the expansion part connection unit 122 is cylindrical and encloses the opposite ends of the base part connection unit 121. The expansion part connection unit 122 pivots by sliding on the cylindrical end surfaces of the base part connection unit 121. The cylinder length of the expansion part connection unit 122 is substantially the same as the width 109 of the base part 100 and the expansion part 110, while the length of the base part connection unit 121 is normally shorter.

Note that the expansion part connection unit 122 could alternatively be a solid cylinder, and the base part connection unit 121 could be cylindrical and enclose the opposite ends of the expansion part connection unit 122.

In addition, the open angle of the extension in the open position 32 is substantially 180 degrees above, but may be any desired angle between 90 degrees and 270 degrees. The configuration of the semiconductor card 30 enabling the expansion part 110 to pivot on the expansion part connection unit 122 and base part connection unit 121 as shown in FIG. 1A, FIG. 1B, and FIG. 1C is referred to herein as a “pivotable configuration.”

Furthermore, while a pivotable configuration is shown in FIG. 1C, a configuration enabling the expansion part 110 to extend by sliding over the base part 100 as shown in FIG. 1D is also conceivable. More specifically, the base part 100 in this configuration has a base part connection unit 121A instead of the base part connection unit 121 shown in FIG. 1C. This base part connection unit 121A is located at one end of the length 108 of the base part 100.

The expansion part 110 includes an expansion part connection unit 122A instead of the expansion part connection unit 122 shown in FIG. 1C. The expansion part connection unit 122A is located on one end of the length 108 of the expansion part 110. The expansion part connection unit 122A is connected to the base part connection unit 121A so that it can slide on the base part connection unit 121A.

The expansion part 110 can be set to either of two positions with the expansion part connection unit 122A connected to the base part connection unit 121A. A first position is the closed position 31 where the expansion part 110 is folded over to and substantially parallel with the base part 100 (shown in the front view 60C in FIG. 1D). A second position is the open position 32 shown in front view 60E of FIG. 1D to which the expansion part 110 extends through an angle perpendicular to the base part 100. More specifically, the angle formed by the expansion part 110 to the base part 100 when in the open position 32 is greater than or equal to 90 degrees and less than or equal to 180 degrees.

In the closed position 31, the inside surface 115 of the expansion part 110 is opposite the inside surface 105 of the base part 100 with a specific distance therebetween, and the outside surface 116 of the expansion part 110 and the outside surface 106 of the base part 100 face in opposite directions.

In the configuration shown in FIG. 1D, the inside surface 115 of the expansion part 110 faces the inside surface 105 of the base part 100 in the open position 32 and the closed position 31. The expansion part 110 can slide in the direction of arrow 119 between the closed position 31 (expansion part 110A in front view 60E) and the open position 32 (expansion part 110B in front view 60E), and can be held at the desired position therebetween. When the pushbutton switch 61 is pressed in the closed position 31, a spring mechanism not shown causes the expansion part 110 to protrude so that it can be pulled to the open position 32 (expansion part 110B). The expansion part 110 is held by a latch mechanism not shown in the open position 32 so that it does not move easily when minimal force is applied. When a greater force is applied to push the expansion part 110 from the open position 32 to the closed position 31 (expansion part 110A), a lock mechanism not shown holds the expansion part 110 in the closed position 31. The configuration of the semiconductor card 30 enabling the expansion part 110 to pivot between the expansion part connection unit 122A and base part connection unit 121A as shown in FIG. 1D is referred to herein as a “sliding mechanism.”

FIG. 2 is an oblique view showing the semiconductor card 30 inserted to an electronic device 220.

FIG. 3A is a section view showing the semiconductor card 30 inserted to the electronic device 220.

FIG. 3B is an oblique view of the card socket 240.

The semiconductor card 30 can be inserted to a card slot 310 rendered in the electronic device 220. The semiconductor card 30 can also be connected to a card socket 240 rendered inside the card slot 310. The terminal part 140 of the base part 100 can engage the card socket 240. When the semiconductor card 30 is a SDIO card, the card socket 240 conforms to the SD card specification.

The thickness 41 of the semiconductor card 30 in the closed position 31 is substantially equal to the combined thickness of the base part 100, the thickness of the expansion part 110, and the distance between the inside surface 105 of the base part 100 and the inside surface 115 of the expansion part 110.

In addition, the thickness 41 of the semiconductor card 30 is substantially equal to the base part connection unit 121 and expansion part connection unit 122.

The thickness of the expansion part 110 is equal to or less than the thickness of the base part 100.

The thickness of the base part 100 is slightly less than the thickness 40 of the card socket 240.

The thickness 42 of the card slot 310 is approximately twice the thickness 40 of the card socket 240 conforming to the SD card standard, for example. Note that FIG. 3A is not drawn to scale and shows the thickness of the expansion part 110, for example, relatively larger than actual. The thickness of the expansion part 110 and the distance between the inside surface 105 of the base part 100 and the inside surface 115 of the expansion part 110 are adjusted so that the thickness 41 of the semiconductor card 30 in the closed position 31 is slightly less than the thickness 42 of the card slot 310.

The length 108 of the base part 100 is shorter than the depth of the card slot 310, and the length of the expansion part 110 is shorter than the length 108 of the base part 100. With these relative dimensions, when the terminal part 140 is engaged with the card socket 240 in the closed position 31, the semiconductor card 30 can be stored completely inside the card slot 310, including the base part 100 and the expansion part 110, so that no part thereof protrudes outside the card slot 310. As shown in FIG. 3A, the side 51 of the semiconductor card 30 on the base part connection unit 121 side, and the side 52 on the expansion part connection unit 122 side, are substantially flush with the side 50 of the electronic device 220, and are slightly inside the card slot 310 from the side 50 of the electronic device 220.

When in the open position 32 such as shown in FIG. 1C (pivotable configuration) or front view 60E in FIG. 1D (sliding configuration), the base part 100 is housed inside the card slot 310 when the terminal part 140 is engaged with the card socket 240 as shown in FIG. 3A, and at least part of the expansion part 110 protrudes outside the card slot 310 (that is, outside the electronic device 220). More specifically, with the pivotable configuration, the expansion part connection unit 122 is inside the card slot 310, and the parts of the expansion part 110 other than the expansion part connection unit 122 are outside the card slot 310. With the sliding configuration, part of the expansion part connection unit 122A is outside the card slot 310, and the rest of the expansion part 110 is inside the card slot 310. Thus when the terminal part 140 is engaged with the card socket 240 in the closed position 31, the base part 100 and expansion part 110 are inserted to the card slot 310. When in the open position 32 and the terminal part 140 is engaged with the card socket 240, the base part 100 is inserted to the card slot 310 and at least part of the expansion part 110 protrudes to the outside from the card slot 310.

The electronic device 220 can be held or carried with the semiconductor card 30 inserted in the open position 32 as described next using the pivotable configuration.

The semiconductor card 30 is in the open position 32, the base part 100 is inserted to the card slot 310, and the terminal part 140 is plugged into the card socket 240. In this case, the terminal part 140 is removed from the card socket 240 and the semiconductor card 30 is pulled out from the card slot 310. The semiconductor card 30 is then changed from the open position 32 to the closed position 31 outside the card slot 310. All of the semiconductor card 30, including the expansion part 110, is then inserted to the card slot 310 and the terminal part 140 is plugged into the card socket 240. If the sliding configuration is used, the semiconductor card 30 can be slid between the closed position 31 and the open position 32 while the terminal part 140 remains plugged into the card socket 240, and there is no need to take the semiconductor card 30 out of the card slot 310.

The semiconductor card 30 can thus be set to two positions, a closed position 31 and an open position 32. In the closed position 31, the semiconductor card 30 can be housed completely inside the card slot 310, including the expansion part 110, and in the open position 32 at least part of the expansion part 110 protrudes to the outside of the electronic device 220 from the card slot 310.

As a result, the semiconductor card 30 can be positioned to optimally orient the antenna for good wireless reception when in the open position 32 using at least a part of the expansion part 110 protruding from the card slot 310. In the closed position 31, no part of the semiconductor card 30 protrudes from the electronic device 220, damage to the semiconductor card 30 can therefore be prevented, and portability of the electronic device 220 is improved. In addition, because the semiconductor card 30 can be carried inside the electronic device 220, loss of or damage to the semiconductor card 30 resulting from being handled separately can be prevented.

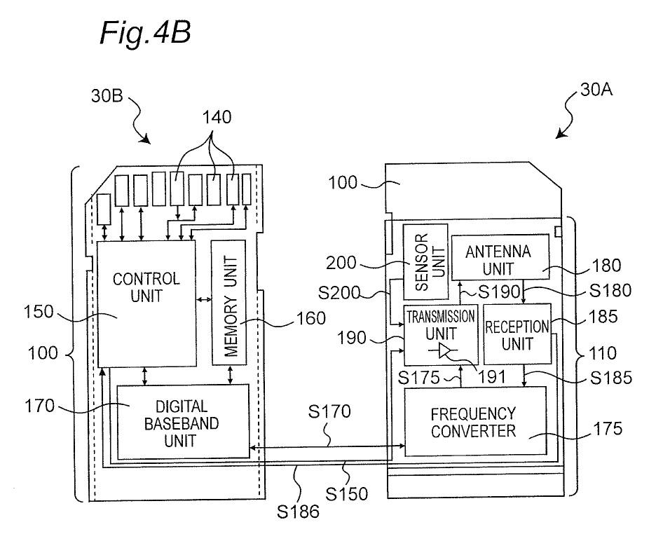

FIG. 4A includes a plan view 30A and a bottom view 30B showing the circuit configuration of the semiconductor card 30. The plan view 30A shows the circuit configuration of the expansion part 110, and the bottom view 30B shows the circuit configuration of the base part 100.

The base part 100 includes a control unit 150, memory unit 160, and digital baseband unit 170. The expansion part 110 includes a frequency converter 175, transmission unit 190, reception unit 185, sensor unit 200, and antenna unit 180. Note that the control unit 150, memory unit 160, digital baseband unit 170, frequency converter 175, reception unit 185, and sensor unit 200 may be contained in the base part 100 or the expansion part 110, or they may be divided between the base part 100 and the expansion part 110.

The terminal part 140 can be electrically connected to the main part of the electronic device 220 through the card socket 240 when plugged into the card socket 240. The main part of the electronic device 220 refers to the major part of the electronic device 220 not including parts such as the card socket 240. The control unit 150 receives and stores data from the electronic device 220 through the terminal part 140 to the memory unit 160 according to the SD card interface protocol.

The memory unit 160 is flash memory, for example. The digital baseband unit 170 receives the data stored in the memory unit 160 directly or through the control unit 150. Based on this data, the digital baseband unit 170 executes a digital baseband transmission process including a process modulating signals for wireless communication, and generates a digital baseband signal S170, which is the signal processed for digital baseband transmission.

The frequency converter 175 frequency converts the digital baseband signal S170 to a desirable frequency band, and outputs the frequency-converted signal as the transmission signal S175.

The transmission unit 190 includes a amplifier 191. The transmission unit 190 amplifies the transmission signal S175 by means of the amplifier 191, and outputs the signal amplified to the desired transmission power as amplified transmission signal S190.

The antenna unit 180 wirelessly transmits the amplified transmission signal S190.

The antenna unit 180 also receives wireless communication signals and generates reception signal S180. The reception unit 185 amplifies the reception signal S180 and outputs amplified reception signal S185.

The frequency converter 175 frequency converts the amplified reception signal S185 to the baseband, and outputs the frequency-converted signal as digital baseband signal S170.

The digital baseband unit 170 executes a digital baseband reception process including a demodulation process based on the digital baseband signal S170.

The control unit 150 receives the data output from the digital baseband reception process, and outputs to the electronic device 220 through the terminal part 140 according to the SC card interface protocol while talking with the memory unit 160.

The reception unit 185 could also detect the signal reception level of the reception signal S180 so that the transmission power of the transmission unit 190 is controlled based on the signal reception level. More specifically, the reception unit 185 in this configuration detects the signal reception level of the reception signal S180 and outputs level detection signal S186.

The control unit 150 then generates control signal S150 based on the level detection signal S186. When the signal reception level is low, the control unit 150 determines that the other device (party) is relatively far and sets the control signal S150 level high. When the signal reception level is high, the control unit 150 determines that the other device (such as the base station) is relatively close and sets the control signal S150 level low. Note that these high and low levels of the control signal S150 are only one example of control states that could be used.

When the control signal S150 goes from low to high, the transmission unit 190 increases the gain of the amplifier 191 to increase transmission power. When the control signal S150 goes from high to low, the transmission unit 190 decreases the gain of the amplifier 191 to decrease transmission power. As a result, transmission performance can be improved when the other party is relatively far, and power consumption and heat output can be reduced when the other party is relatively close.

Transmission performance as used here is the ability to transmit RF signals so that they will reach the other party (receiving party) with a sufficient signal reception level. Note that the transmission unit 190 may be controlled directly by the level detection signal S186 to adjust the transmission power without going through the control unit 150.

The expansion part 110 can touch the electronic device 220 when the terminal part 140 is plugged into the card socket 240 in the closed position 31. More specifically, as shown in FIG. 1B, FIG. 1C, and FIG. 3A, the expansion part 110 includes a heat sink 130 that facilitates dissipation of heat from the expansion part 110.

The heat sink 130 is affixed to the inside surface 115 of the expansion part 110, and if shaped like a flat spring can contact the top surface 241 of the card socket 240 with a desirable elastic modulus. Particularly heat produced by the transmission unit 190 of the expansion part 110 can be dissipated by heat conduction through the heat sink 130, card socket 240, and circuit board 230 to the main part of the electronic device 220.

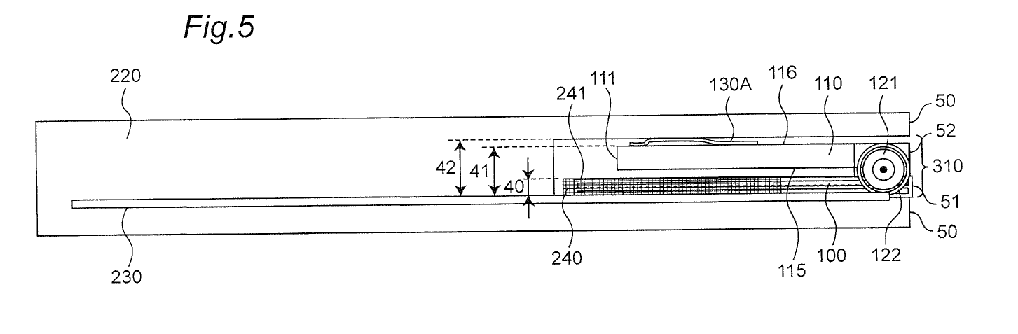

The expansion part 110 may use a heat sink 130A configured as shown in FIG. 5 instead of the foregoing heat sink 130. This heat sink 130A is attached to the outside surface 116 of the expansion part 110. By shaping the heat sink 130A like a flat spring similarly to the heat sink 130 described above, the heat sink 130A can contact the card slot 310 with the desired elastic modulus. Heat produced in the expansion part 110 particularly by the transmission unit 190 can be dissipated by heat conduction to the main part of the electronic device 220 through the heat sink 130A.

Referring to FIG. 4, the sensor unit 200 detects contact between the expansion part 110 and electronic device 220, and outputs contact detection signal S200. More specifically, the sensor unit 200 detects contact between the heat sink 130 and the top surface 241 of the card socket 240, and generates the contact detection signal S200. The expansion part 110 may electrically contact the electronic device 220, or mechanically contact the electronic device 220 while being electrically isolated therefrom. When the expansion part 110 electrically contacts the electronic device 220, the sensor unit 200 detects change in the voltage of the card case 111 rendering the surface of the expansion part 110, for example. Alternatively, the sensor unit 200 detects change in current flow through the card case 111 forming the surface of the expansion part 110. Further alternatively, the sensor unit 200 detects change in inductance between ground and the card case 111 forming the surface of the expansion part 110.

The control unit 150 generates the control signal S151 based on the contact detection signal S200. The control unit 150 sets the control signal S151 high when the contact detection signal S200 is output, and sets the control signal S151 low when the contact detection signal S200 is not output. These high and low states of the control signal S151 are examples of one control state.

When the control signal S151 goes from low to high, the transmission unit 190 increases the range of the amplifier 191 to increase the maximum transmission power level. When the control signal S151 goes from high to low, the transmission unit 190 decreases the range of the amplifier 191 to decrease the maximum transmission power. For example, when the control signal S151 is high, the transmission unit 190 increases the maximum transmission power approximately 20% greater than when the control signal S151 is low. As a result, transmission performance can be improved when heat dissipation through heat conduction is sufficient, and prevents heat damage to the amplifier 191 by limiting transmission power when heat loss is insufficient.

Alternatively, the transmission unit 190 could directly increase or decrease the maximum transmission power based on the contact detection signal S200 without going through the control unit 150. In this configuration the transmission unit 190 receives the contact detection signal S200 directly from the sensor unit 200 as shown in FIG. 4B. More specifically, when the contact detection signal S200 is output (that is, there is a change from a no-contact to a contact state), the transmission unit 190 increases the maximum gain of the amplifier 191 to increase the maximum transmission power. When contact detection signal S200 output stops (that is, there is a change from a contact to a no-contact state), the transmission unit 190 decreases the maximum gain of the amplifier 191 to decrease the maximum transmission power.

Further alternatively, a configuration in which the sensor unit 200 generates a high temperature signal when the temperature of the expansion part 110 exceeds a specified level, and the transmission unit 190 controls the amplifier 191 to decrease the maximum transmission power of the transmission unit 190 when the high temperature signal is output, is also conceivable. As a result, a temperature rise in the expansion part 110 can be suppressed, and the function and performance of the semiconductor card 30 can be protected.

As described above, when the terminal part 140 is plugged into the card socket 240 in the closed position 31, the semiconductor card 30, including the expansion part 110, is housed inside the card slot 310. The signal reception level of the reception unit 185 drops in this case because the antenna contained in the expansion part 110 can be freely positioned. When the transmission power of the transmission unit 190 is controlled based on the signal reception level of the reception unit 185 as described above, the transmission unit 190 increases transmission power by boosting the gain of the amplifier 191 when the signal reception level of the reception unit 185 drops. As a result, transmission performance can be sufficiently increased even when the expansion part 110 is housed inside the card slot 310 and the direction of the antenna cannot be moved freely.

In addition, when the expansion part 110 is stored in the card slot 310, heat dissipation through heat convection and heat radiation from the expansion part 110 drops compared with when the protruding part of the expansion part 110 is in the open position 32 exposed to open air. However, the expansion part 110 is touching the electronic device 220 as described above, and heat from the transmission unit 190 is sufficiently dissipated by thermal conduction to the electronic device 220. As a result, the heat radiation effect of the expansion part 110 in the closed position 31 is greater than when in the open position 32, and a rise in the temperature of the expansion part 110 can be suppressed.

Because the heat dispersion effect of the expansion part 110 is thus high even when the transmission power of the transmission unit 190 is increased when the expansion part 110 is installed in the card slot 310, transmission performance can be sufficiently increased while suppressing a temperature rise in the expansion part 110.

Furthermore, because the contact detection signal S200 is output while the expansion part 110 is stored inside the card slot 310, the transmission unit 190 can increase the maximum transmission power and further boost transmission performance.

When the terminal part 140 is plugged into the card socket 240 in the open position 32, at least part of the expansion part 110 protrudes outside the electronic device 220. Because the direction of the antenna in the expansion part 110 can be moved freely in this case, the signal reception level of the reception unit 185 can be boosted compared with when the expansion part 110 is stored inside the card slot 310. As described above, if the signal reception level of the reception unit 185 rises when the transmission power of the transmission unit 190 is controlled based on the signal reception level of the reception unit 185, the transmission unit 190 reduces the transmission power by reducing amplifier 191 gain. As a result, when at least part of the expansion part 110 protrudes outside the electronic device 220 and the direction of the antenna in the expansion part 110 can be moved freely, power consumption and heat output can be reduced with sufficiently high transmission performance.

Furthermore, when at least part of the expansion part 110 protrudes outside the electronic device 220, heat dissipation through heat convection and heat radiation increases compared with when in the closed position 31 because the protruding part of the expansion part 110 is exposed to open air. However, because the expansion part 110 is not in contact with the electronic device 220 as described above, heat conduction by the expansion part 110 is insufficient, and heat dissipation by the expansion part 110 is less when in the open position 32 than in the closed position 31.

Even if heat dissipation by the expansion part 110 is insufficient when part of the expansion part 110 protrudes outside the electronic device 220, transmission performance can be sufficiently increased while suppressing a temperature rise in the expansion part 110 because the transmission power of the transmission unit 190 is reduced.

Furthermore, because the contact detection signal S200 is not output when part of the expansion part 110 protrudes outside the electronic device 220, the transmission unit 190 can decrease the maximum transmission power and prevent thermal breakdown of the amplifier 191.

The expansion part 110 thus includes a transmission unit 190, and can contact the electronic device 220 when in the closed position 31. The semiconductor card 30 includes a sensor unit 200, and the sensor unit 200 can detect contact with the electronic device 220 of the expansion part 110. The transmission unit 190 can increase the maximum transmission power when the expansion part 110 is determined to be touching the electronic device 220 based on the contact detection signal, and decrease the maximum transmission power when the expansion part 110 is not in contact with the electronic device 220.

As a result, when transmission power is increased to increase transmission performance in the closed position 31 because the direction of the antenna cannot be optimized, an increase in the temperature of the expansion part 110 can be suppressed by contact with the electronic device 220, and the function and performance of the semiconductor card 30 can be protected. In addition, the semiconductor card 30 can further improve transmission performance by increasing the maximum transmission power.

However, because the antenna direction can be optimized when in the open position 32, transmission power can be decreased while transmission performance remains high, and a temperature rise in the expansion part 110 can be suppressed without contact with the electronic device 220. In addition, by reducing the maximum transmission power, thermal failure of the transmission unit 190 can be prevented.

### Embodiment 2

A second embodiment of the invention is described below focusing on the differences with the first embodiment. Other aspects of the configuration, operation, and effect of this embodiment are the same as in the first embodiment, and further description thereof is omitted.

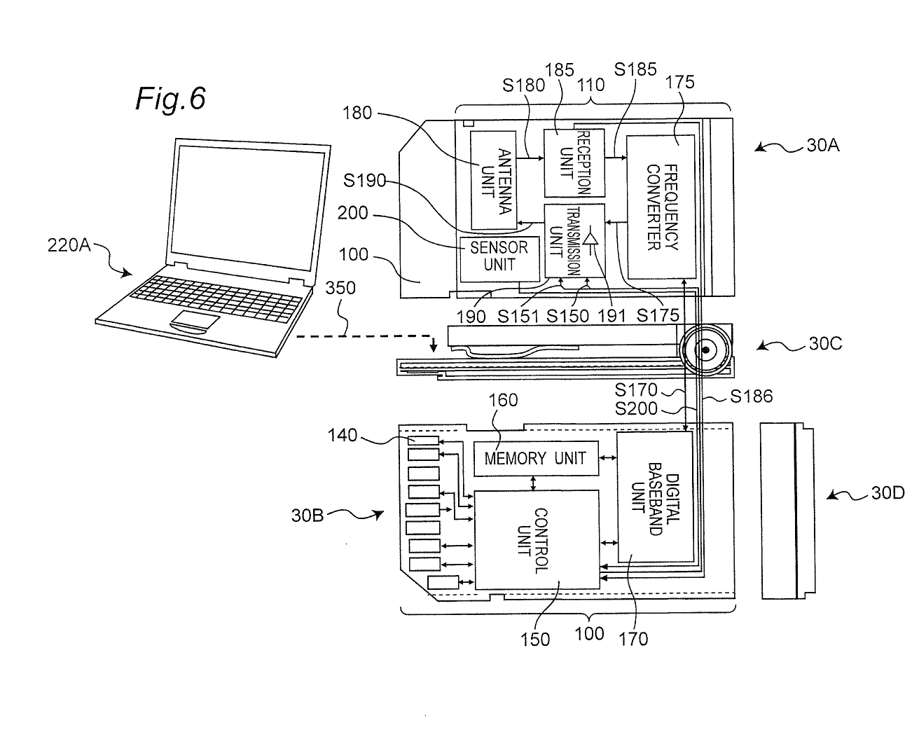

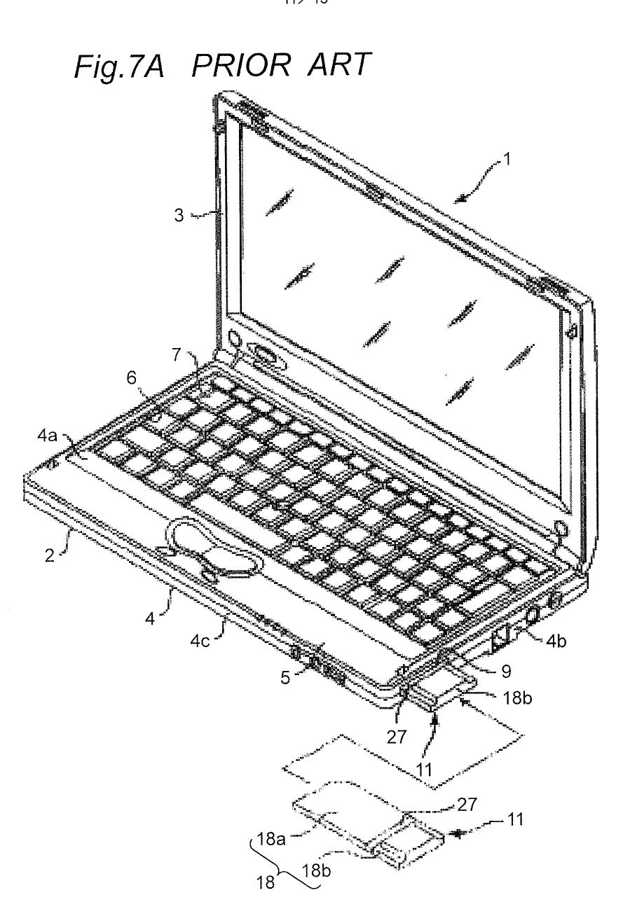

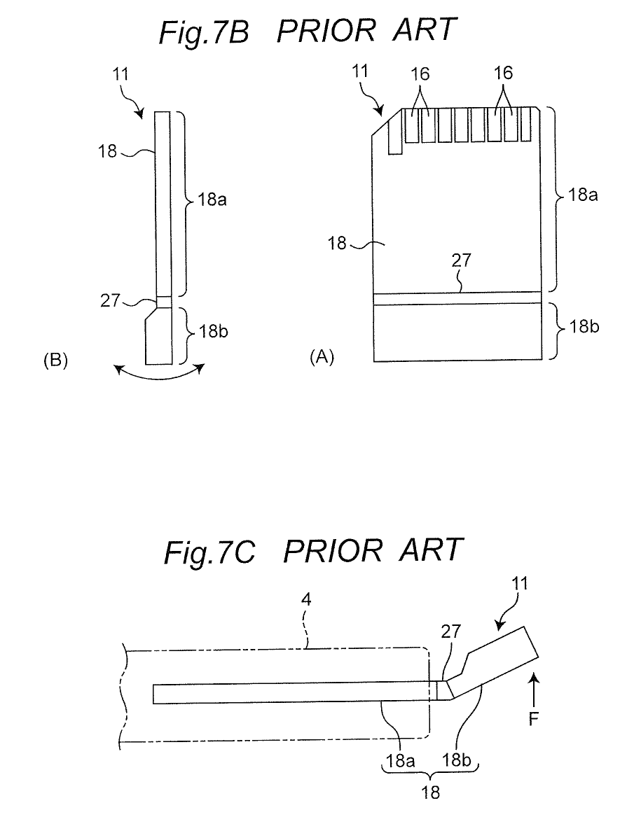

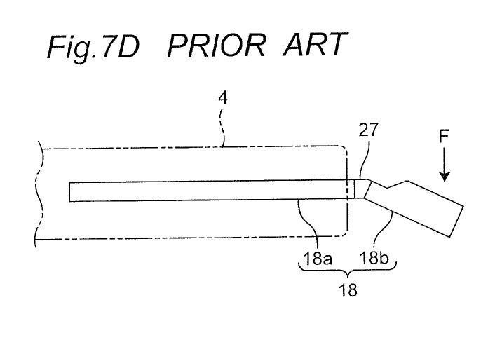

FIG. 6 includes a plan view 30A, bottom view 30B, front view 30C, and side view 30D showing the circuit configuration of the semiconductor card 30, and an oblique view showing an electronic device 220A.

In FIG. 6 the semiconductor card 30 shown in plan view 30A, bottom view 30B, front view 30C, and side view 30D is inserted to the electronic device 220A, which in this embodiment of the invention is a laptop computer.

The electronic device 220A includes a lithium ion battery or other type of storage battery as a DC power source. The electronic device 220A also includes a low battery signal generating unit. The low battery signal generating unit monitors the remaining capacity of the storage battery, and generates a low battery warning signal 350 when the remaining battery capacity drops below a specified level. More specifically, the low battery warning signal 350 indicates that the remaining capacity of the storage battery is low.

When the low battery warning signal 350 is received through the terminal part 140 from the low battery signal generating unit, the control unit 150 sets the control signal S151 low. When the control signal S151 goes low from high, the transmission unit 190 controls the amplifier 191 to decrease the maximum transmission power.

The electronic device 220A could use a primary battery instead of a storage battery, in which case the low battery signal generating unit monitors the capacity of the primary battery and generates the low battery warning signal 350 when the battery capacity drops below a specified level.

This embodiment of the invention suppresses power consumption when the battery that powers the electronic device 220A is low, and can thus increase the operating time of the electronic device 220A.

### Conclusion

As described above, the semiconductor card 30 can be set to two positions, a closed position 31 and an open position 32. The semiconductor card 30 and the expansion part 110 thereof can be completely stored inside the card slot 310 in the closed position 31. In the open position 32, at least part of the expansion part 110 protrudes outside the electronic device 220 from the card slot 310.

As a result, the semiconductor card 30 can be positioned to optimally orient the antenna for good wireless reception when in the open position 32 using at least a part of the expansion part 110 protruding from the card slot 310. In the closed position 31, no part of the semiconductor card 30 protrudes from the electronic device 220, damage to the semiconductor card 30 can therefore be prevented, and portability of the electronic device 220 is improved. In addition, because the electronic device 220 can be held and carried with the semiconductor card 30 thereinside, loss of or damage to the semiconductor card 30 resulting from being handled separately can be prevented.

The expansion part 110 thus includes a transmission unit 190, and can contact the electronic device 220 when in the closed position 31. The semiconductor card 30 includes a sensor unit 200, and the sensor unit 200 can detect contact with the electronic device 220 of the expansion part 110. The transmission unit 190 can increase the maximum transmission power when the expansion part 110 is determined to be touching the electronic device 220 based on the contact detection signal, and decrease the maximum transmission power when the expansion part 110 is not in contact with the electronic device 220.

As a result, when transmission power is increased to increase transmission performance in the closed position 31 because the direction of the antenna cannot be optimized, an increase in the temperature of the expansion part 110 can be suppressed by contact with the electronic device 220, and the function and performance of the semiconductor card 30 can be protected. In addition, the semiconductor card 30 can further improve transmission performance by increasing the maximum transmission power.

However, because the antenna direction can be optimized when in the open position 32, transmission power can be decreased while transmission performance remains high, and a temperature rise in the expansion part 110 can be suppressed without contact with the electronic device 220. In addition, by reducing the maximum transmission power, thermal failure of the transmission unit 190 can be prevented.

In the embodiments described above the semiconductor card 30 includes a base part 100 and expansion part 110, and either the base part 100 or the expansion part 110 may include the devices shown in FIG. 4, that is, the control unit 150, memory unit 160, digital baseband unit 170, frequency converter 175, transmission unit 190, sensor unit 200, and antenna unit 180.

However, the base part 100 may represent a frame (support structure) including the terminal part 140 and base part connection unit 121 instead of the devices shown in FIG. 4, and the expansion part 110 may represent a frame including an expansion part connection unit 122 instead of the devices shown in FIG. 4. In this configuration, the semiconductor card 30 includes the base part 100 and expansion part 110 separately from the circuit components shown in FIG. 4, and the devices shown in FIG. 4 are appropriately disposed to the base part 100 or the expansion part 110. A semiconductor card 30 thus rendered differs from the foregoing embodiments only in the disposition of the foregoing circuit devices to the base part 100 or expansion part 110, and all other aspects of the foregoing descriptions of the embodiments still apply.

Note that numbers used in the foregoing description of the invention are used by way of example only to describe the invention in detail, and the invention is not limited thereto. Logic levels denoted as high and low are also used by way of example only to describe the invention, and it will be obvious that by changing the configuration of the logic circuits the same operation and effect can be achieved by logic levels different from those cited in the foregoing embodiments. Yet further, some components that are rendered by hardware can also be rendered by software, and some components that are rendered by software can also be rendered by hardware. Furthermore, some of the elements described in the foregoing embodiments can be reconfigured in combinations that differ from the foregoing embodiments to achieve the particular effects of such different configurations while not departing from the scope of the invention.

### Industrial Applicability

The invention can be used with semiconductor cards.

The invention being thus described, it will be obvious that it may be varied in many ways. Such variations are not to be regarded as a departure from the spirit and scope of the invention, and all such modifications as would be obvious to one skilled in the art are intended to be included within the scope of the following claims.

1. A semiconductor card that is insertable to a card slot in an electronic device and engagable to a card socket formed inside the card slot, comprising:
a base part having a terminal part and a first connection unit, the terminal part being engagable to the card socket; and
an expansion part having a second connection unit, the expansion part being movable between two positions when the second connection unit is connected to the first connection unit, a closed position where the expansion part is overlapping and substantially parallel to the base part, and an open position where the expansion part is extended at an angle greater than a perpendicular with respect to the base part;
wherein
when the expansion part is in the closed position and the terminal part is engaged in the card socket, the expansion part and the base part are inserted to the card slot, and
when the expansion part is in the open position and the terminal part is engaged in the card socket, the base part is inserted to the card slot and at least a part of the expansion part protrudes from the card slot.

2. A semiconductor card described in claim 1, wherein:
the expansion part pivots between the closed position and the open position.

3. A semiconductor card described in claim 1, wherein:
the expansion part slides between the closed position and the open position.

4. A semiconductor card described in claim 1, further comprising:
a sensor unit; wherein
the expansion part includes a transmission unit, the expansion part contacts the electronic device when the expansion part is in the closed position and the terminal part is engaged in the card socket;
the sensor unit detects contact between the expansion part and the electronic device, and produces a contact detection signal; and
the transmission unit includes an amplifier, and when the contact detection signal is produced, the amplifier is controlled such that a transmission power range of the transmission unit is increased.

5. A semiconductor card described in claim 4, wherein:
the expansion part is able to contact at least one of the card socket and the card slot.

6. A semiconductor card described in claim 4, wherein:
the expansion part includes a heat dissipation unit that facilitates heat dissipation from the expansion part and is able to contact at least one of the card socket and the card slot.

7. A semiconductor card described in claim 4, further comprising:
a control unit that generates a control signal.

8. A semiconductor card described in claim 7, wherein:
the control unit sets the control signal to a first control state when the contact detection signal is produced, and sets the control signal to a second control state when the contact detection signal is not produced; and
the transmission unit increases the range of the transmission power when the control signal changes from the second control state to the first control state, and decreases the range of the transmission power when the control signal changes from the first control state to the second control state.

9. A semiconductor card described in claim 7, wherein:
the control unit sets the control signal to a specific control state when a low battery warning signal indicating the capacity of the electronic device battery is low is received from the electronic device through the terminal part; and
the transmission unit decreases the range of transmission power when the control signal goes to the specific control state.

10. A semiconductor card described in claim 4, wherein:
the sensor unit detects contact between the expansion part and at least one of the card socket and the card slot.

11. A semiconductor card described in claim 4, wherein:
the sensor unit detects electrical contact between the expansion part and the electronic device.

12. A semiconductor card described in claim 11, wherein:
the sensor unit detects a voltage change in the card case forming a surface of the expansion part.

13. A semiconductor card described in claim 11, wherein:
the sensor unit detects a change in current flow in the card case forming a surface of the expansion part.

14. A semiconductor card described in claim 11, wherein:
the sensor unit detects a change in inductance between ground and the card case forming a surface of the expansion part.

15. A semiconductor card described in claim 4, wherein:
the sensor unit produces a high temperature signal when the temperature of the expansion part exceeds a predetermined temperature; and
the transmission unit controls the amplifier and reduces the range of transmission power of the transmission unit when the high temperature signal is produced.

16. A semiconductor card described in claim 4, wherein:
the transmission unit increases the range of transmission power.

17. A semiconductor card described in claim 4, wherein:
the terminal part is able to connect electrically through the card socket to the main part of the electronic device.

18. A semiconductor card described in claim 4, wherein:
the expansion part includes an antenna unit;
the transmission unit amplifies the transmission signal by the amplifier, and generates a transmission signal having an amplified transmission power; and
the antenna unit transmits the amplified transmission signal as a radio signal.

19. An electronic device that uses the semiconductor card described in claim 1.
